(19) United States
(12) Patent Application Publication
(10) Pub. No.: US 2007/0077676 A1
(43) Pub. Date: Apr. 5, 2007

(54) METHOD OF FABRICATING PRESSURE SENSOR

(76) Inventors: Shih-Feng Shao, Taipei Hsien (TW); Chen-Hsiung Yang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/308,305

(22) Filed: Mar. 15, 2006

(30) Foreign Application Priority Data
Sep. 30, 2005 (TW) 094134230

(51) Int. Cl. H01L 21/46

(52) U.S. Cl. 438/51; 438/456

(57) ABSTRACT

A method of fabricating a pressure sensor. An SOI wafer having a single crystalline silicon layer, an insulating layer and a silicon substrate is provided. The single crystalline silicon layer has a pressure sensing device. The silicon substrate and the insulating layer corresponding to the pressure sensing device are removed to form a cavity. A bonding substrate is adhered to the silicon substrate with a bonding layer.

### BACKGROUND OF THE INVENTION

1. Field of the Invention

The present invention relates to a method of fabricating a pressure sensor, and more particularly, to a method that forms the pressure sensing device on an SOI wafer, forms the cavity of the pressure sensor by deep etching techniques, and bonds the SOI wafer and a bonding substrate with adhesive resin or glass frit.

2. Description of the Prior Art

Pressure sensor is a common micro electro mechanical system (MEMS) device, and piezoresistive pressure sensor is the most popular one in all types of pressure sensors. Refer to FIG. 1 to FIG. 3. FIG. 1 to FIG. 3 are schematic diagrams illustrating a conventional method of fabricating a piezoresistive pressure sensor. As shown in FIG. 1, an epitaxy wafer including a silicon substrate 10, and an epitaxy layer 12 disposed on the silicon substrate 10 is provided. A plurality of piezoresistors 14 are subsequently formed in the epitaxy layer 12. These piezoresistors 14 are connected as a Wheaston bridge via connecting wires (not shown).

As shown in FIG. 2, an anisotropic wet etching process is performed using potassium hydroxide (KOH) solution to etch the silicon substrate 10 from the back surface to form a cavity (back chamber) 16 exposing the epitaxy layer 12. As shown in FIG. 3, a glass wafer 18 is then provided and bonded to the silicon substrate 10 by anodic bonding.

The conventional method of fabricating a piezoresistive pressure sensor however suffers from some disadvantages. First, the epitaxy growth of the epitaxy layer 12 has low yield and high cost. If the epitaxy layer 12 has poor quality, the etching of the silicon substrate 10 cannot accurately stop on the surface of the epitaxy layer 12, and this causes damages to the piezoresistors 14 disposed in the epitaxy layer 12. In addition, the sidewall of the cavity 16 formed by KOH solution has an included angle of about 54.7 degrees, and this inclined sidewall generates invalid areas, reducing the device integration. Furthermore, the glass wafer 18 has to meet two requirements for anodic bonding. First, the glass wafer 18 must contains a certain amount of sodium so as to implement anodic bonding. Second, the thermal expansion coefficient of the glass wafer 18 must be close to that of the silicon substrate 10 so as to prevent thermal stress issue due to temperature changes. The glass wafer 18 meeting these two requirements is more expensive than a normal glass wafer. Moreover, the silicon substrate 10 and the glass wafer 18 are different materials, and therefore a cutter with a specific standard is required in the successive segment process. In addition, in order to comply with the glass wafer 18, the cutting rate of the silicon substrate 10 (normally between 30 to 40 mm/sec) must be reduced to the cutting rate of the glass wafer 18 (normally between 5 to 10 mm/sec). This seriously affects the production efficiency.

### SUMMARY OF THE INVENTION

It is therefore one of the objectives of the claimed invention to provide a method of fabricating a pressure sensor to improve the yield and the device integration, and to reduce the cost.

According to the claimed invention, a method of fabricating a pressure sensor is provided. First, an SOI wafer including a single crystalline silicon layer, an insulating layer, and a silicon substrate is provided. The single crystalline silicon layer includes a pressure sensing device. Subsequently, the silicon substrate and the insulating layer corresponding to the pressure sensing device is removed to form a cavity. Following that, a bonding substrate is provided, and the silicon substrate and the bonding substrate are bonded together with a bonding layer.

According to the claimed invention, a method of fabricating a pressure sensor is provided. First, a device substrate including a pressure sensing device disposed in a front surface is provided. Then, the device substrate corresponding to the pressure sensing device is removed from a back surface of the device substrate to form a cavity. Subsequently, a bonding substrate is provided, and the device substrate and the bonding substrate are bonded together with a bonding layer. The bonding layer may be an adhesive resin or a glass frit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic diagrams illustrating a conventional method of fabricating a piezoresistive pressure sensor.

FIG. 4 to FIG. 8 are schematic diagrams illustrating a method of fabricating a pressure sensor in accordance with a preferred embodiment of the present invention.

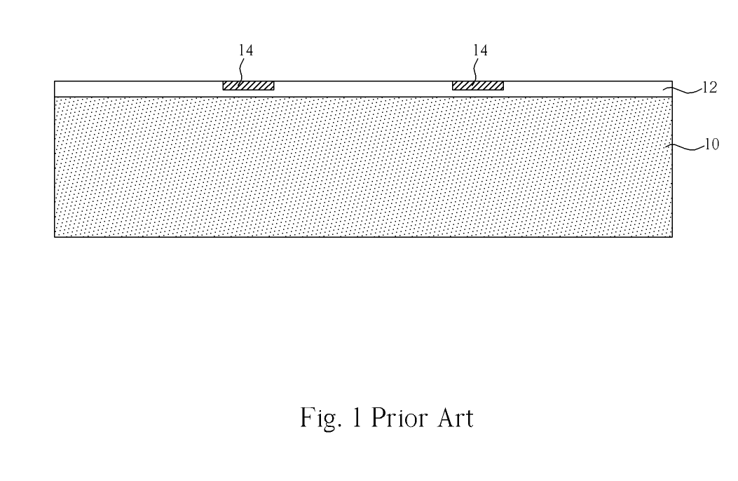

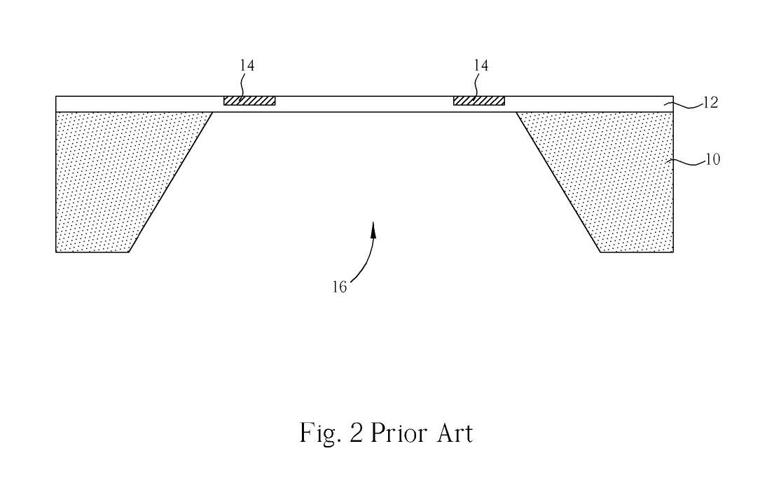

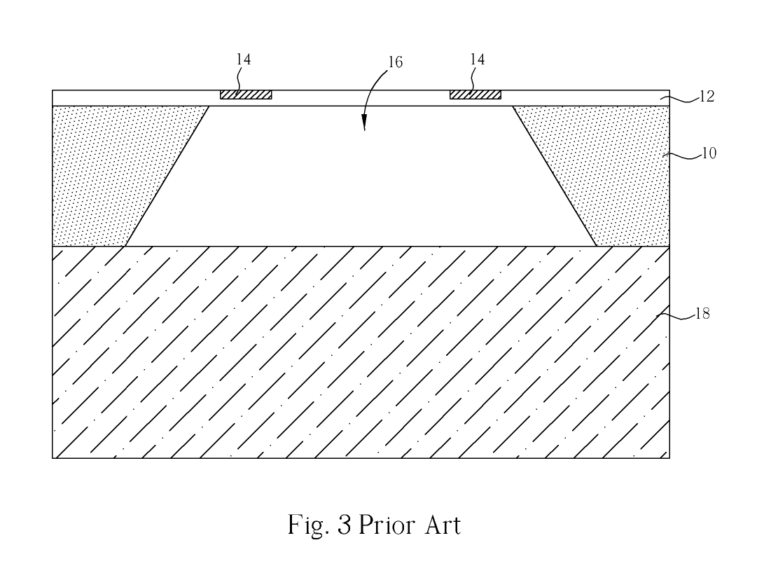

### DETAILED DESCRIPTION

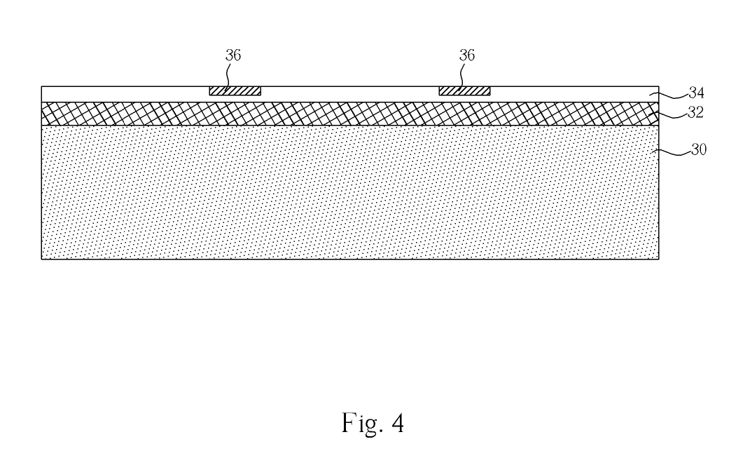

Refer to FIG. 4 to FIG. 8. FIG. 4 to FIG. 8 are schematic diagrams illustrating a method of fabricating a pressure sensor in accordance with a preferred embodiment of the present invention. This embodiment uses a piezoresistive pressure sensor as an example to illustrate the present invention, and the figures only show one single pressure sensor to highlight the feature of the present invention. As shown in FIG. 4, a silicon-on-insulator (SOI) wafer is provided as a device wafer. The SOI wafer includes a silicon substrate 30, an insulating layer 32 e.g. an oxide layer, and a single crystalline silicon layer 34 from bottom to top. Subsequently, a pressure sensing device is formed in the single crystalline silicon layer 34. The pressure sensing device includes a plurality of piezoresistors 36 formed by implantation process, and connecting wires (not shown) formed by photolithography and deposition techniques. These piezoresistors 36 are connected as a Wheaston bridge, and are responsible for converting pressure signals into amplified voltage signals.

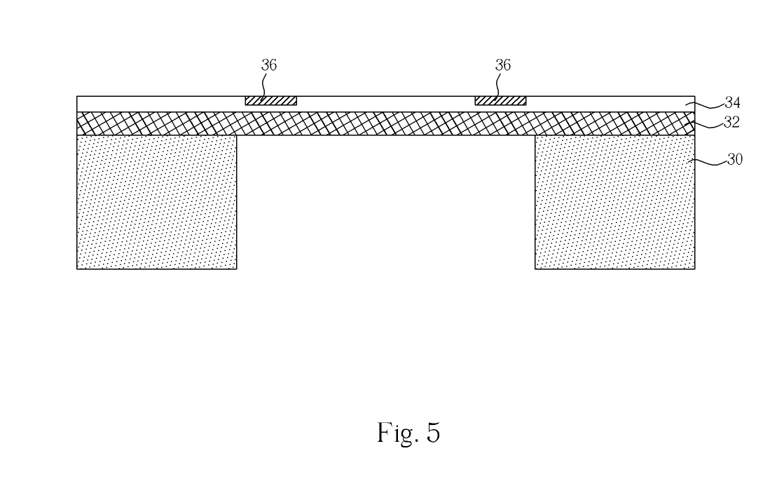

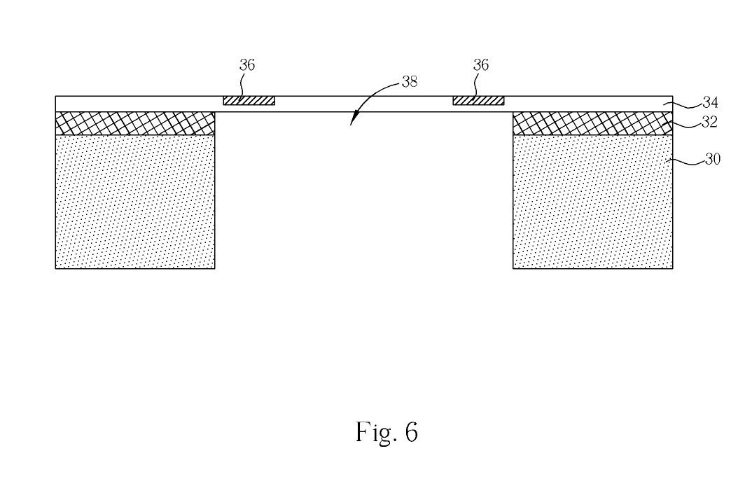

As shown in FIG. 5, a masking pattern (not shown) is formed on the back surface of the silicon substrate 30, and an anisotropic dry etching process such as a reactive ion etching process, an inductively coupled plasma reactive ion etching process, an electron cyclotron resonance plasma etching process, or a deep X-ray lithography process is performed. The anisotropic dry etching process etches the silicon substrate 30, and stops on the insulating layer 32. As shown in FIG. 6, another etching process is performed to etch the exposed insulating layer 32, and the etching stops on the single crystalline silicon layer 34 to form a cavity 38. The masking pattern is then removed. It is appreciated that the etching selectivity between the insulating layer 32 and the single crystalline silicon layer 34 is good, and therefore the single crystalline silicon layer 34 is not damaged due to over-etching. Accordingly, the quality of the pressure sensing device is ensured. In addition, the cavity 38 formed by an anisotropic dry etching process has a vertical sidewall, and thus the actual area of the pressure sensor is reduced.

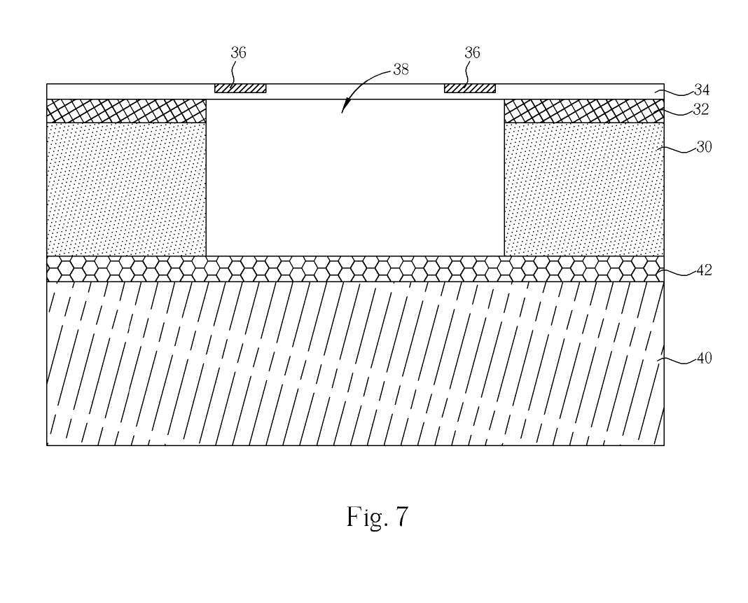

As shown in FIG. 7, a bonding substrate 40 is provided, and a bonding layer 42 is used to adhere the bonding substrate 40 to the silicon substrate 42. In this embodiment, adhesive resin or glass frit is used as the material of the bonding layer 42. If adhesive resin 42 e.g. UV tape, benzocyclobutene (BCB), polyimide, epoxy, photoresist or dry film is used, the bonding substrate 40 can be any suitable substrate such as glass substrate, plastic substrate, quartz substrate or semiconductor wafer. On such a condition, the bonding substrate 40 can be any poor-quality wafer or even a discarded wafer. As a result, the manufacturing cost is reduced. If glass frit (normally mixtures of glass powders and solvent, or adhesives containing glass) is used, the bonding furthers has an advantage of airtightness. It is appreciated that if the bonding substrate 40 is a silicon wafer that is the same material as the silicon substrate 30, the thermal stress issue may be prevented, and the cutting rate is not necessarily reduced.

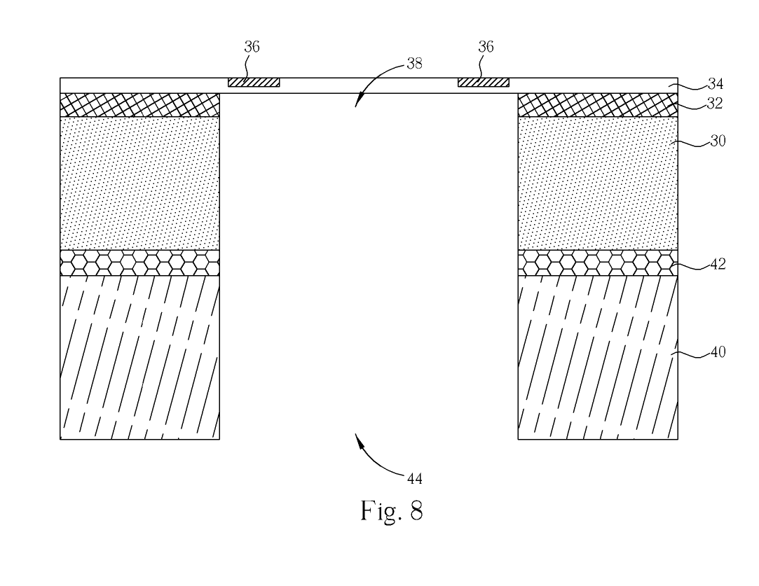

In addition, the application of the pressure sensor may differ. For instance, if the pressure sensor is used in a manometer, the bonding substrate 40 must have an opening. As shown in FIG. 8, an etching process is performed to form an opening 44 after the bonding substrate 40 and the silicon substrate 30 is adhered. However, the opening 44 is not limited to be formed before the cavity 38 is formed. For example, the bonding substrate 40 may be adhered to the silicon substrate 30 with the bonding layer 42 in advance, and the opening 44 and the cavity 38 are formed later. Particularly, the opening 44 and the cavity 38 can be formed by the same anisotropic etching process if the bonding substrate 40 is a silicon wafer. In addition, if the bonding substrate 40 is plastic substrate or glass substrate, the opening 44 can be formed in advance by injection molding or mechanical machining for reducing cost and cycle time. It is also appreciated that the method of the present invention is not limited to fabricate piezoresistive pressure sensors, and can be used to form all types of pressure sensors or MEMS devices having a cavity (back chamber).

In summary, the method of the present invention has the following advantages:

1) The SOI wafer ensures the reliability of pressure sensor;

2) The anisotropic dry etching used to form the cavity improves the device integration; and

3) The use of adhesive resin or glass frit increase flexibility of the bonding substrate material, and further prevents thermal stress problem.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a pressure sensor, comprising:
providing an SOI wafer, the SOI wafer comprising a single crystalline silicon layer, an insulating layer, and a silicon substrate, the single crystalline silicon layer comprising a pressure sensing device;
removing the silicon substrate and the insulating layer corresponding to the pressure sensing device to form a cavity; and
providing a bonding substrate, and bonding the silicon substrate and the bonding substrate with a bonding layer.

2. The method of claim 1, wherein removing the silicon substrate corresponding to the pressure sensing device is achieved by an anisotropic dry etching process.

3. The method of claim 2, wherein the anisotropic dry etching process comprises a reactive ion etching process, an inductively coupled plasma reactive ion etching process, an electron cyclotron resonance plasma etching process, or a deep X-ray lithography process.

4. The method of claim 1, wherein the insulating layer is an oxide layer.

5. The method of claim 1, wherein the bonding layer is an adhesive resin.

6. The method of claim 1, wherein the bonding layer is a glass frit.

7. The method of claim 1, further comprising forming an opening in the bonding substrate corresponding to the cavity subsequent to bonding the silicon substrate and the bonding substrate.

8. The method of claim 1, further comprising forming an opening in the bonding substrate corresponding to the cavity prior to bonding the silicon substrate and the bonding substrate.

9. The method of claim 1, wherein the bonding substrate is a wafer.

10. The method of claim 1, wherein the bonding substrate comprises a glass substrate, a plastic substrate or a quartz substrate.

11. A method of fabricating a pressure sensor, comprising:
providing a device substrate, the device substrate comprising a pressure sensing device disposed in a front surface;
removing the device substrate corresponding to the pressure sensing device from a back surface of the device substrate to form a cavity; and
providing a bonding substrate, and bonding the device substrate and the bonding substrate with a bonding layer, wherein the bonding layer comprises an adhesive resin or a glass frit.

12. The method of claim 11, where the device substrate is an SOI wafer comprising a single crystalline silicon layer, an insulating layer, and a silicon substrate, and the pressure sensing device is disposed in the single crystalline silicon layer.

13. The method of claim 12, wherein forming the cavity comprises removing the silicon substrate and the insulating layer corresponding to the pressure sensing device.

14. The method of claim 13, wherein removing the silicon substrate corresponding to the pressure sensing device is achieved by an anisotropic dry etching process.

15. The method of claim 14, wherein the anisotropic dry etching process comprises a reactive ion etching process, an inductively coupled plasma reactive ion etching process, an electron cyclotron resonance plasma etching process, or a deep X-ray lithography process.

16. The method of claim 11, further comprising forming an opening in the bonding substrate corresponding to the cavity subsequent to bonding the device substrate and the bonding substrate.

17. The method of claim 11, further comprising forming an opening in the bonding substrate corresponding to the cavity prior to bonding the device substrate and the bonding substrate.

18. The method of claim 11, wherein the bonding substrate is a wafer.

19. The method of claim 11, wherein the bonding substrate comprises a glass substrate, a plastic substrate or a quartz substrate.
